(19) United States
(12) Patent Application Publication
(10) Pub. No.: US 2026/0230212 A1
(43) Pub. Date: Aug. 6, 2026

(54) RECEIVER WITH REAL-TIME SPECTRUM ANALYZER PROVIDING STATION IDENTIFIERS

(71) Applicant: Sound Devices LLC, Reedsburg, WI (US)

(72) Inventors: Matthew G. Anderson, Madison, WI (US); Tanner Breisch, Verona, WI (US)

(73) Assignee: Sound Devices LLC, Reedsburg, WI (US)

(21) Appl. No.: 19/530,625

(22) Filed: Feb. 5, 2026

Related U.S. Application Data
(60) Provisional application No. 63/754,789, filed on Feb. 6, 2025.

(51) Int. Cl. H04H 60/44; G01R 23/16; H04H 60/43

(52) U.S. Cl. CPC H04H 60/44; G01R 23/16; H04H 60/43

(57) ABSTRACT

Methods and devices are provided for a real time spectrum analyzer (RTSA) to run live on a wireless microphone receiver system whereby text labelling, graphical identifiers and background-shading may be added to the display to allow users to more easily differentiate frequency regions that are likely to be affected by RF emissions from external devices that may influence available the signal to noise ratio for a wireless microphone transmitter and receiver pair. Frequency bands allocated to DTV channels operating within the configurable frequency range of the receiver transmitter pair are identified on a live RTSA scan displayed on the receiver display.

### CROSS-REFERENCE TO RELATED PATENT APPLICATION

The present application claims the benefit of U.S. Provisional Application Ser. No. 63/754,789, filed Feb. 6, 2025, which is incorporated by reference herein in its entirety.

### FIELD OF THE INVENTION

The disclosed invention provides means to improve the ease and reliability associated with configuring a wireless microphone system. It does so by providing additional features to a real time spectrum analyzer (RTSA) display on a receiver or receiver module. It also provides a graphical visual aid to assist users in identifying and establishing a unique frequency band for connections between wireless microphone transmitting and receiving unit pairs. It provides new tools for simplifying the task of avoiding frequency bands that are prone to external interference and that are allocated for digital television (DTV) transmission.

### BACKGROUND

Wireless microphone systems are becoming increasingly popular due to the convenience and flexibility offered by cordless operation. They allow performers additional freedom for active movement while engaged in performances on stage. In order to operate, these systems must maintain a wireless link for data communication between each wireless microphone transmitter and an assigned (paired) receiver. The wireless transmitter can be part of the wireless microphone or in many cases the microphone is connected by a wire to the wireless microphone transmitter. The wireless microphone transmitters are often placed in close proximity with the microphones themselves and in some cases are carried by or directly attached to performers while on stage. In contrast, wireless microphone receivers are often located at a stationary location closer to a sound equipment cart or desk where work being performed by a sound technician (henceforth referred to as a “user”) often includes operating a microphone mixer/recorder system for recording, mixing, broadcast and/or playback. The collection of these wireless microphones along with their respective transmitter and receiver pairs, mixer unit, recording unit (if present) and other supporting equipment that may be stationed at or in the vicinity of an equipment cart and stage are referred to as a “wireless microphone environment”. Sound bags holding receivers and mixer recorders are often used in field production.

When configuring a wireless microphone environment, a user must often assign various wireless microphone transmitter and receiver pairs to operate in specific (dedicated) frequency bands that are selected from within a predetermined range. This type of operation is called frequency division multiplexing. When a user configures a particular wireless microphone receiver with a corresponding paired wireless transmitter that particular receiver unit is referred to as the “receiver transmitter pair” or more simply as an “RTP”. In order to use and configure these in an optimal fashion, a user often times will set details on configuration such as assigning a frequency band for each wireless microphone RTP. In order to transmit audio data over an RF link, multiple types of modulation may be utilized, depending on the environment, physical limitations for power output (batteries) and government regulations that limit available broadcast frequencies, power and bandwidth. In some embodiments, phase shift keying (PSK) may be preferred. Other types of modulation may include quadrature phase shift keying (QPSK), frequency modulation (FM, frequency shift keying (FSK) or amplitude shift keying (ASK). Ideally, however, to maximize performance, a unique frequency band that is not otherwise occupied by a communication signal from another wireless device should be allocated to each pair. In one example, the receiver can be set to operate in the range of 169 MHz to 1525 MHz which often includes commercial TV channels that are commonly broadcast in the U.S., especially at the lower end of the spectrum. If the frequency band selected for use by a wireless microphone overlaps portions of the frequency domain that are already occupied by another signal being broadcast (such as a DTV station or other “original” wireless devices), this may result in a compromised signal-to-noise-ratio (SNR) for the microphone signal, as well as possibly interfering with the function for the other (original) devices attempting to communicate with each other. In some cases, this may violate governmental regulations intended to protect the integrity and accessibility of the original RF transmissions such as reception for DTV stations.

Previous attempts to mitigate the risk of RF signal interference have included the use of a real-time spectrum analyzer (RSTA). When this is applied as a dedicated stand-alone device, it can require a relatively expensive piece of equipment. A multi-coupler can be used to feed the signal from the receiver antenna to the RTSA allowing the RTSA to dynamically show a trace for the level of measured RF signal energy versus frequency on its display screen. The trace updates several times per second and gives the user a real time visual indication of any transmitters being received by the receiver antenna as well as other interference on the antenna. Fortunately, many functions of an RTSA may be embedded into a modern receiver for use as an option utilizing resources that are already present on the device such as an FPGA and touch-screen display at modest expense. A built-in RTSA allows the user to identify bands where relatively low levels of RF interference are likely to exist, but its use requires that the user own, carry and attach the needed equipment. In order to avoid the need for interacting with an RTSA, some receivers include a frequency scan feature in which antenna signals are measured as the frequency is slowly scanned. The receiver displays an updated graph for the RF power levels (often with dBm power levels displayed vertically along the y-axis) as a function of frequency (horizontally spanning the x-axis), for the total RF levels present for all nearby devices (including all wireless microphone transmitter and receiver pairs and any other detected equipment emitting RF signals in the vicinity). The plot representing the RF power spectrum is displayed and updated over time or when requested (refreshed once every several seconds or more). Such frequency scans do not enable the user to see the dynamic movement of the RF power spectrum in real time like an RTSA, which is a drawback of the typical scan feature. For example, it is helpful to identify the temporal behavior of a given transmitter, e.g., determining whether the signal is consistent in real time, and the typical receiver scan feature does not provide adequate information to do so.

The present invention is related to a prior invention entitled: “Receiver Integrated Real-Time Spectrum Analyzer” that was filed as U.S. Utility patent application Ser. No. 18/508,383 on Nov. 14, 2023 (referred to hereafter as the “'383 application”), by Matthew Anderson and James Gordon, assigned to the assignee of the present application and incorporated by reference herein. Most aspects of the '383 application are cross-compatible with use of the present invention. This will become evident to one skilled in the art upon reading (and in many cases pointed out by) details of the following disclosure.

In one aspect, the invention in the '383 application is directed to the incorporation of a real-time spectrum analyzer (RTSA) into a receiver or receiver module. FIG. 5 is similar to FIGS. 5A and 5B in the '383 application and shows an exemplary circuit that enables the practical implementation of an RTSA into a receiver or receiver module. The circuit in FIG. 5 provides this feature for a single antenna, but the concept can be extended to multiple antennas for the receiver. For example, it may be desirable in some cases to display an RSTA trace from two or more antennas on the receiver display.

Another aspect of the invention in the '383 application is directed to the ability to separately identify the frequency regions for the trace due to the receiver being tuned from the RF power that may be affected by other channels or sources. For example, the trace for RF levels in a given frequency band may result from a number of sources, including the wireless microphone itself. In order to reduce the risk of assigning a frequency band for the wireless microphone, contributions to the overall RF level that occur due to other source may be color-coded and labelled as described in the '383 application.

The invention in the '383 application can be implemented in a microphone receiver module having one or more wireless microphone receiving units that remain operative when attempting to continue receiving wireless information from corresponding microphone transmitter units. In order to properly communicate, a user may assign a unique RF band to each wireless microphone RTP such that each RF band will allow for a sufficient SNR that it may provide a data rate that reliably supports the communicating of audio data. In one embodiment, multiple receiver units are integrated into one or more receiver modules. Rather than directly integrating the receiver modules into the mixer/recorder, a module may be kept separate where it may be either directly connected to the mixer/recorder module or when desired, placed at a nominal distance (usually in the direction of the transmitter units) and connected via a wired connector or another wireless connection to the mixer/recorder module. This connection between a receiver module and the mixer/recorder module may also be either wired or wireless Ethernet and the receiver module may process the audio information into a “Digital Audio through Ethernet” (DANTE) compatible format before transmitting it to the mixer/recorder module. A receiver module may collect and analyze information received from each transmitter unit to construct the best possible representation of information (audio waveform) originally detected and sent by the microphone elements. The resultant audio information or constructed waveform is supplied to one or more mixer/recorder endpoints (or a mixer/recorder module). This requires the information regarding the pairing of each wireless microphone receiver and transmitter and associated RF band to be determined at some point in preparation for use as part of a wireless microphone environment.

In some circumstances, operations performed by the receiver module may include dynamically selecting an RF band sent by the transmitter module that has the lowest error rate in its decoded audio signal. In other circumstances, it may select decoded information received by the receiver module reporting the highest signal strength from the microphone module. In yet other embodiments, the decoded information from multiple receiver modules may be blended together with decoded information from multiple receiver modules to produce a decoded signal that is higher quality than what would otherwise be possible from information received from a single receiver module. Based on this, the mixer/recorder module reconstructs (and may optionally output) electrical waveforms or data representative of the original audio signal.

This resultant output from the receiver module may then be recorded, broadcast, mixed with other audio sources and/or played back to listeners via headphone or loudspeaker arrangement. In some embodiments, the microphone transmitter modules themselves will encode audio waveform data to reduce bandwidth requirements. In these cases, the step of decoding the data for the actual audio waveform (audio PCM data) may be performed at either each receiver module, the mixer/recorder module or at a later time if this data is to be recorded.

The invention in the '383 application also contemplates systems using multiple receiver modules having the described RTSA feature built-in for its antennas. The receiver modules can be placed in a distributed manner on a set or on a stage, and the RTSA trace information can be shared among the other receiver modules or a central hub for display. This can be accomplished using Ethernet connections between the receiver modules. This aspect of the invention in the '383 application can be implemented for example in connection with the diversity receiver technique disclosed in U.S. Pat. No. 10,433,084, by Matt Anderson, entitled “Network System for Reliable Reception of Wireless Audio,” issuing on Oct. 1, 2019, which is incorporated by reference.

Some aspects of the invention in the '383 application may be implemented in receivers that provide an RF scan feature instead of an RTSA trace as described. For example, the ability to separately identify the portion of an RF scan due to a receiver channel being tuned from an RF scan due to other channels or other sources is useful even without the use of an RTSA. The portion of the scan corresponding to the frequency band for a given tuned receiver channel can be displayed in one color and the remainder of the scan can be displayed in another color. Also, the receiver can be programmed to enable the user to name the portion of the RF scan corresponding to the selected channel frequency band and also label the portion of the RF scan corresponding to the selected channel frequency band with the name when the scan is displayed.

As mentioned above, some commercial DTV channels are commonly broadcast in the U.S within the range of 169 MHz to 1525 MHz, which is the spectrum that the receiver in the exemplary embodiments of the invention operates. The present invention improves the receiver RTSA described in the '383 application by providing tools to identify and avoid frequency bands that are occupied by a local active DTV station or while also identifying other frequency bands used by other wireless devices attempting to communicate with each other.

### SUMMARY

In one embodiment, the present invention is a wireless receiver in a sound recording system similar to that described in the '383 application but also having the capability to determine and display allocated frequency bands, such as frequency bands used by local digital television stations. The display screen on the receiver that displays the RTSA trace in real time also displays selected allocated frequency bands on the display screen thereby rendering it easier to set the receiver/transmitter frequency band to a clean frequency. For example, in some embodiments, it may be advantageous to identify frequency regions corresponding to the RF signal from a digital television station (DTV) with a shading and/or text label, while identifying RF signal components due to other wireless audio equipment with a second (different) shading or text label, while labeling the RF component due to the wireless microphone with yet another shading, box or text label. Rather than color coding traces on the RTSA (as disclosed in the '383 application), it can be simpler (more intuitive for the user) for some applications to simply place a marker box around distinct RF components or directly labeling with text on the display.

More specifically, the invention pertains to a real-time spectrum analyzer (RTSA) in the receiver or receiver module that generates an RTSA trace from an antenna signal, which can be blended from more than one physical antenna. As mentioned, the RTSA trace is displayed in real time for the user view on the receiver display. In accordance with the present invention, the means to determine allocated frequency bands, such as frequency bands allocated to active DTV channels, are provided on the receiver or receiver module. The allocated frequency bands are identified on the receiver display when the RTSA trace is displayed in real time. In some embodiments, the means to determine the allocated frequency bands comprises an algorithm to automatically detect the presence of active DTV channels from the RTSA trace data. In this way, active DTV channels are automatically identified on the display of the RTSA trace, so the user can easily consider the information when selecting RF transmission frequencies for the receiver channels. As an option, once the algorithm detects a given DTV channel to be active, the given DTV channel remains an allocated frequency band that is identified on the display until the receiver or receiver module is rebooted.

Alternatively, the means to determine allocated frequency bands can comprise a database of allocated frequency bands, such as DTV channels, where the allocated frequency bands identified on the display are selected by the user or are based on geographic location input such as user entered zip code or automatically generated from GPS data.

Other features and advantages of the present invention are discussed below in connection with the drawings.

### BRIEF DESCRIPTION OF THE DRAWINGS

FIG. 1 is a diagram showing a frontal viewof an array of wireless receivers mounted side by side into a receiver module. This may be accomplished by constructing a rack-mounted system or alternatively a wireless receiver module wherein several receiver units may be slotted in or built together into a single unit. In this example, a total of four touch-screen control panel/displays are arranged side-by-side, one each for the four wireless microphone receivers contained in this module. The receiver module has two antennas in this example.

FIG. 2 shows an RTSA trace (zooming in to display better detail for a single display from the unit of FIG. 1) on a receiver display screen in accordance with the invention, where the trace results from RF components contributed by a known DTV station 105C (“WXYZ DTC CH-26”), a known wireless audio channel 105B (“Audio Ch1”) and a few detected sources (having uncertain origin) 105A1, A2 are depicted on the screen.

FIG. 3 illustrates the exemplary RTSA trace on the display screen s as in FIG. 2, where the portion of the trace for the frequency band for RF components are labeled and identified by colored boxes drawn directly on the display.

FIG. 4 illustrates another version of the exemplary RTSA trace in FIGS. 2 and 3 where the presence of an active DTV channel is graphically indicated by providing vertical bars surrounding the allocated frequency bands and optionally back-shading to distinguish the allocated frequency band from other bands in use.

FIG. 5 shows a block diagram illustrating various stages for a method of generating data an RTSA trace to display on a receiver display screen according to a first exemplary embodiment of the invention.

FIG. 6 shows a block diagram illustrating various stages for a method of generating data for an RTSA trace to display on a receiver display screen according to a second exemplary embodiment of the invention.

FIG. 7 is a diagram illustrating a process of automatically detecting active DTV channels, assigning allocated frequency bands and displaying the allocated frequency bands on the RTSA scan on the receiver display screen.

FIG. 8 is a diagram illustrating an exemplary algorithm implemented in a processor in the receiver for automatically detecting whether a given DTV channel is active.

### DETAILED DESCRIPTION

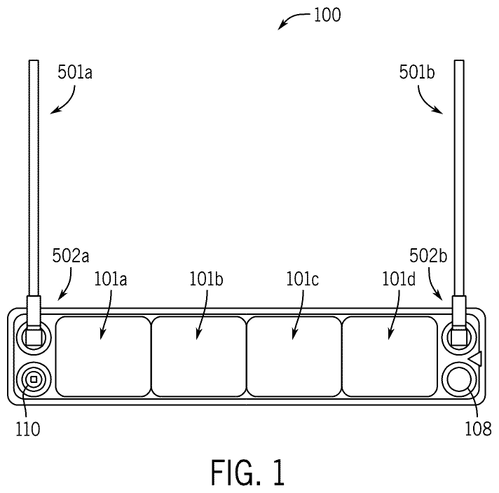

FIG. 1 shows a receiver module 100 with a series of four touchscreen display screens101a, 101b, 101c and 101d (where each is hereafter generically referred as a “touchscreen display” 101). The touchscreen displays 101a, 101b, 101c and 101d are located side-by-side to be conveniently accessible from the front side of the containing equipment chassis. In this example, each touchscreen display 101a, 101b, 101b and 101d may be assigned to a single stereo (2 channel) wireless microphone (for a total of eight channels in this example). In this example, control and configuration for each receiver unit is accomplished from user input collected via a hierarchy of interactive nested control menus accessible from its touchscreen display 101a, 101b, 101c or 101d. This arrangement may be achieved either by a rack mount system where receiver units individually plug into mechanical slots provided in the rack system or by a microphone receiver module where the function for these displays 101 and associated wireless microphone receiver units are all built into a singular module 100. These touchscreen displays 101 may be programmed to serve both as a user interface for programming and/or configuring any given RTP and as an interactive display providing status, data and live information while in operation. In addition to the touchscreen displays 101a-d, this receiver module 100 may have a control knob/button 108. The receiver module 100 also has antennas 501a, 501a, mounted on either side of the multi-channel receiver module 100. In the disclosed example, the antennas 501a, 501b serve to receive RF signals intended for any of the receiver units contained in the receiver module 100. While these are shown in a parallel configuration in FIG. 1, they may be attached such that they may be rotated (or swiveled) at their base 501a, 501b to point in any preferred direction. In many cases, orientating them in an orthogonal pattern (to receive RF signals of any polarity) may be preferable. It should be noted that the invention can be implemented on receiver modules having a single antenna, two antennas, or multiple antennas. In contrast to this example, other embodiments may include those where touchscreen displays may be arranged (rather than in a single row) in multiple rows or a grid pattern.

The initial pairing of the receiver and the microphone transmitter in this embodiment is accomplished via a USB-c connection when the products are originally set up for use. Prior to pairing, the receiver and the transmitter can communicate configuration information using a “backlink”, e.g., a 2.4 GHz frequency hopping communications (back) channel.

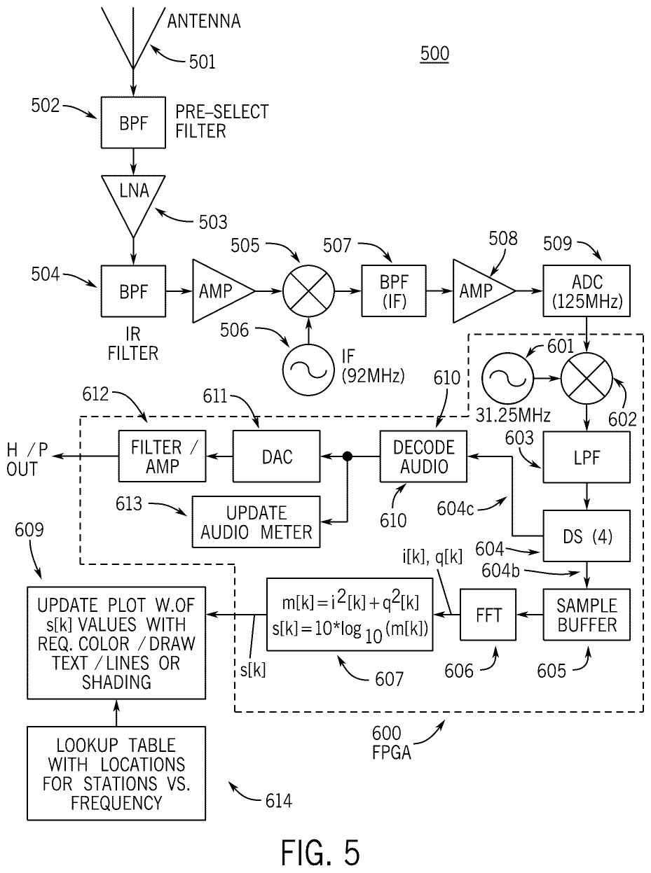

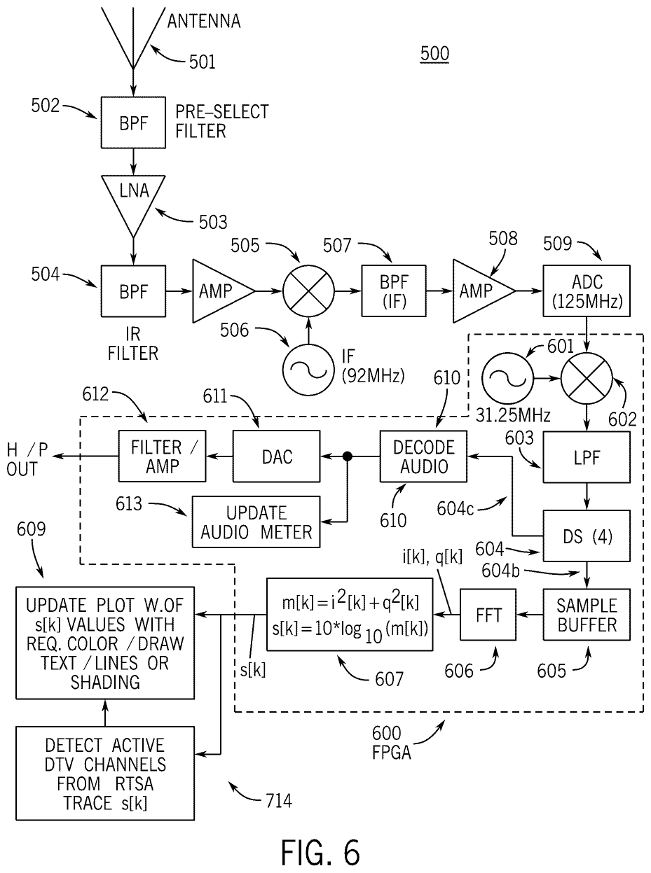

For a given locality (for example, a zip-code within the United States) a list of commercially broadcast stations and their respective broadcasting frequencies may be derived from public information provided by the FCC or other agencies. In accordance with the embodiment of the invention described in connection with FIG. 5, this data may be collected and tabulated by a manufacturer (referred to as a “station database”) to be included for reference on a wireless device. Based upon a location reference that may be provided by a user or automatically derived using GPS features that are built into the device, a list of stations and their respective broadcast frequencies may be made available to aid in the annotation of spectral peaks identified in the RTSA trace as it is collected during setup. It may be preferable to allow a device to download such a table (or collection of them) from a manufacturer via WIFI link. For other embodiments, a user may download and provide such a file from a manufacturer during an initial product setup phase (to be completed immediately after) purchase (possibly using a USB memory device to transfer data). The embodiment of the invention described in connection with FIGS. 6 through 8, in contrast to the embodiment described in FIG. 5, automatically detects the presence of active DTV channels by analyzing the RTSA data in real time.

The modulation used for transmitting wireless audio data from the microphone transmitter may rely on FM, PSK, BPSK, QPSK, etc.) or spread-spectrum techniques. Other elements not shown that may be part of the design for the microphone transmitter module include a mechanical housing for structural support, various circuits, power supplies, batteries, adapters, clips, amplifiers, companders, limiters, denoising algorithms, signal conditioners or filters, analog to digital converters, communications circuits, modulators, antennas, microprocessors, FPGAs, digital signal processors and/or software for configuration, control and operation of the microphone module that will be apparent to one skilled in the art.

Station identifiers may be placed into the live RTSA trace even at time when station broadcasting is not active. For example, if at a given time a station is inactive, the existence of this station may be inferred from the station database. From this, an identifier may be placed in the RTSA to alert a user that a given frequency range may become less suitable for the transmission of wireless microphone data in the near future in the event that the broadcast for such a station could resume at which time, the station broadcast and wireless microphone signals could interfere with each other.

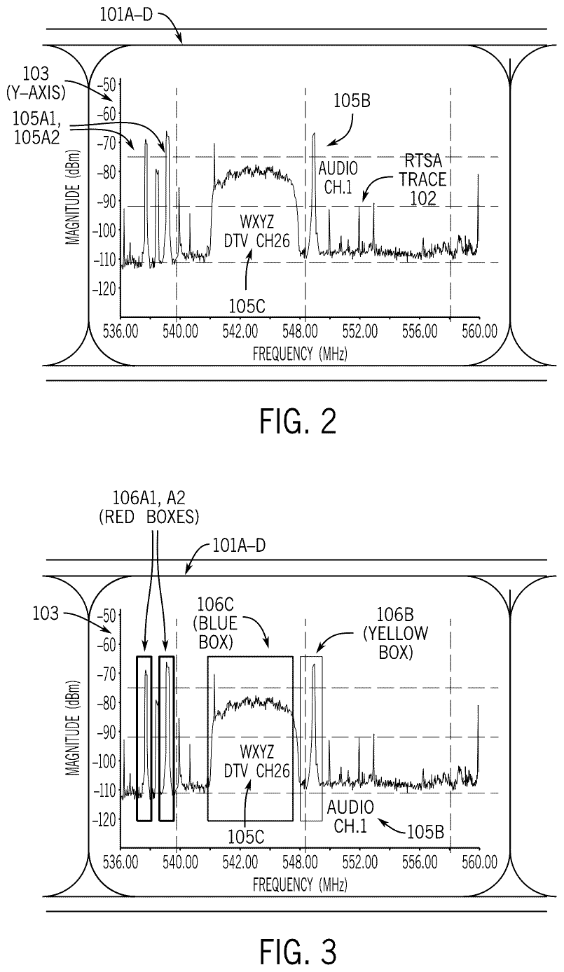

FIG. 2 illustrates an expanded view of one of the touchscreen displays 101a-d, where a user may enter commands prompting the device to provide an RTSA trace 102 on a display screen 101a-d that will allow the user to better understand the RF environment in which an RTP is to operate. As shown in this example, the RTSA trace 102 includes a swath of higher energy levels having a bandwidth of approximately 6 MHz and a center frequency at 545 MHz, labelled 105C and “WXYZ DTC CH-26”. It also shows a block of energy, having a bandwidth of about 200 kHz that could be attributed to a wireless audio channel 105B. In some cases, an increase in RF energy may be attributed to a known RTP using another channel, having previously been assigned to the receiver. For example, to indicate this, another RTP signal (assigned as channel 1) detected by the RTSA 105B may be labeled as “Audio Ch 1”, on the display. In this embodiment, the height of the RTSA trace 102 indicates the power level in dBm as referenced to the y-axis scale 103. The position along the x-axis is referenced with respect to the labeled frequency in MHz, where a span of 24 MHz may be displayed on each screen 101 a-d, e.g. FIGS. 2-4 show 536 MHz to 560 MHz. In some embodiments, a user may smoothly swipe their finger to the left or right along the touch screen to cause the displayed frequency range to scroll to a higher or lower range, respectively. Further embodiments envisioned by this disclosure include those whereby using two fingers at the same time on the touch screen 101 and either drawing them horizontally closer together or further apart, the user may compress or expand, respectively, the displayed frequency range until a desired range is displayed on the touch screen. For other embodiments, a vertical swipe of a finger on the display may be used to adjust the endpoints for the vertical scale 103 on the display. And similarly, a vertical compression or expansion between two fingers on the display may be used to adjust the span (dBm range) for the vertical scale 103. As shown, two peaks 105A1 and 105A2 in the RF spectrum are illustrated present for this example. However, since the RTP does not operate in isolation, other RF information may be present from other devices (such as wireless microphones from other manufacturers). Assuming that the receiver has no information that peaks like peaks 105A1 and 105A2 are associated with a particular RTP or DTV channel, the peaks 105A1, A2 would not typically be labelled on the display screen.

If at some later time, the transmission for the DTV station were to cease, the power level for the RTSA trace 102 would presumably fall to the noise level within the DTV station band. However, the receiver may be configured to display the “WXYZ DTC CH-26” label (105C) to alert the user that this range may not remain suitable in the event that the DTV station transmission broadcast later resumes.

For some embodiments, a peak-hold feature may be applied to the RTSA display for RF power levels 102. In addition, a relatively simple algorithm operating on the receiver may be used to keep track of how much RF power levels exceed a (noise floor) threshold (that may be user adjustable) and subsequently identify (or warn about) frequency regions that have been (even intermittently) subject to higher RF power levels above a threshold.

In the first exemplary embodiment, the user turns the control knob 108 (FIG. 1) with the receiver 100 in RTSA mode to move a vertical frequency marker to a “clean” frequency band (i.e. where there is low background RF noise). The user then presses the control knob 108 to display a list of receiver channels and selects the appropriate channel to assign the clean frequency. The frequency is automatically pushed to the transmitter, and its RF signal appears in the RTSA trace. Alternatively, touchscreen controls may be used to select a clean frequency and assign it to a given receiver channel. Further, it is possible to select an auto assign function to automatically deploy clean frequencies to all active channels, see incorporated the '383 application which explains that the auto assign feature can be implemented by having the receivers communicate with the transmitters to turn off transmission and then enable the transmitter to turn on one band at a time. This way the system can measure and choose the band with the best SNR characteristics for each RTPUC. As used herein, means for configuring the receiver and a paired microphone transmitter to a selected channel frequency band includes both the manual selection using a control knob or touchscreen controls, or equivalents, as described above and also the auto assign feature described in the '383 application.

The embodiment in FIG. 2 does not use the color-coding for regions of the RTSA trace 102 as described in the '383 application. Accordingly, the user attempting to set up an RTP with a suitable RF operating band might not always be able to identify which peak 105A1, 105A2 or 105B is from the wireless transmitter receiver pair being tuned. In other words, the user may be tempted to assume that the frequency region occupied by the RF transmission (as indicated by the first peak) 105A1 is not available, when it is in fact due to the RTP of interest. This problem of identifying relevant portions of the RF power spectrum often occurs with prior art receivers implementing a scan function.

Another embodiment of the invention is illustrated in FIG. 3. This embodiment addresses the difficulties described above by providing labelled or unlabeled boxes superimposed onto the RTSA trace to conspicuously identify which RF field sources have been assigned over the displayed frequency region. These boxes may themselves be color coded depending on the type of RF transmission that a specific portion of the spectrum has been allocated. For example, a blue box 106C may be drawn around portions of the RF spectrum allocated to DTV transmission, yellow boxes 106B may be used to identify (drawn around) neighboring audio channels and red boxes 106A1 and 106A2 may be drawn around peaks that have unknown origin. This may be applied at the same time as labelling to more clearly indicate what source(s) the displayed RF signal energy originates from. As can be seen in FIG. 3, the RF signal energy associated with the RTP is differentiated from RF signal energy being received by the antenna from other transmitters (or for that matter by any other nearby devices) by color coding (and furthermore labelling 105B if desired). These features remain fully compatible with the improvements described by the '383 application. For example, according to the '383 application, the portion of the trace for the RF spectrum associated with the receiver under configuration may be drawn with an alternate color (such as a yellow rather than green that may be used for other parts of the RF spectra due to equipment other than the RTP). The modulation bandwidth and programmed modulator frequency of the RTP are supplied by the user to the receiver/transmitter pair and are known by the receiver. For some embodiments, users may be given the option of choosing the assignment of color coding with respect to source type. The receiver in turn color codes the identified range on the RTSA trace to indicate that the identified frequency range is in use by the receiver channel and its paired transmitter. This concept can be easily extended to cases where several sources are to be indicated, with additional colors (e.g., blue, red, white, cyan, etc.) that may be applied over different frequency spans of the trace as appropriate. In alternative embodiments, line type (such as dashed, varied thickness or brightness) rather than color may be used to indicate the RF source, as could other indicators, such as shading below portions of the graph. In some embodiments, flashing segments or time varying brightness or thickness could also indicate the RF source.

Still referring to the embodiment shown in FIG. 3, the receiver may be programmed to enable the user to name and label the portion of the RTSA trace 102 corresponding to a selected channel frequency band. For example, in FIG. 2, if a user chooses to assign the name “Bob” to represent the content of Audio Ch 1, the label 105B” may be changed to “Bob” to more clearly identify the portion of the RTSA trace corresponding to the selected channel frequency band.

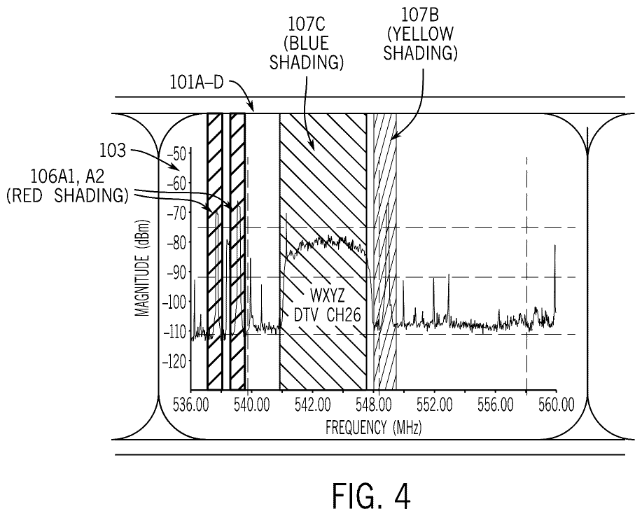

As will be apparent to one skilled in the art, other methods may be utilized to provide users with frequency band allocation information that is both informative and intuitive. For example, according to another embodiment of the invention, background shading may be applied to illustrate frequency regions that have been reserved for other RF sources, as shown in FIG. 4. In this diagram, the frequency region occupied by a DTV channel has been labeled “WXYZ DTV-CH 26”. The region occupied by this channel may be further indicated by the present of a blue shaded background 107C covering this region in the plot. In a similar capacity, frequency regions that are known to be occupied by neighboring sources of unknow origin may be shaded red 107A1, 107A2, as shown in the figure. For some embodiments it may be preferable that a smooth transition take place between shaded and non-sharded portion of the plot to make view more comfortable. For other embodiments, a user selectable feature may be added where the transition is abrupt to aid in clearer viewing, such as when the display is being used in brightly lit environments such as in daylight.

FIG. 5 provides a block diagram for a circuit 500 that is able to perform the functions of a real-time spectrum analyzer (RTSA) and can also be integrated into a receiver, a multi-channel receiver, or other equipment associated with receiver such mixer-recorder with an integrated multi-channel receiver. Referring to FIG. 5, the RTSA circuit 500 generates data representing the power spectrum for an input signal from an antenna which can then be displayed as an RTSA trace. In this embodiment, the RF input signal to be characterized is received by an antenna (or antenna pair) 501 (a physical depiction of the antennas is also referenced by 501a,b in FIG. 1). Immediately after a signal is picked up by the antenna 501, a preselection bandpass filter 502 is applied to reduce out of band signal energy as well as partially reject image band signals. The preselection filter 502 is an analog filter which in this exemplary embodiment allows signal frequencies corresponding to those in an allowed transmission channel having a bandwidth of 24 MHz to pass. The resultant signal is then amplified by a low noise amplifier (LNA) 503. This low noise amplification suppresses the relative contribution of noise by the succeeding stages. Following the LNA 503, the resultant amplified signal is applied as input to an image rejection (IR) filter 504, which is another analog bandpass filter. The LNA 504 in this exemplary embodiment allows signal frequencies corresponding to a single 24 MHz bandwidth channel in the range between 169 MHz and 1525 MHz to pass. Then again, an amplifier is used to bring the signal level up to a suitable level for a mixer 505. The mixer is applied to down-convert the signal from the RF frequency to an intermediate frequency (IF) using the output of a local oscillator 506 set to the intermediate frequency of e.g. 92 MHz. The output of the mixer 505 is then applied as the input to another IF filter 507 (analog bandpass filter) and again amplified using another amplifier 508 such that the signal levels are appropriate (typically a few volts) to be supplied as input to an analog to digital converter (ADC) 509 that may operate at, e.g., 125 MHz.

After the ADC 509 has converted the input signal to a series of digital samples, the digital samples are supplied as the input to an FPGA 600. It should be noted that elements of FIG. 5 that lie inside the block enclosure labeled FGPA 600 are to be considered as implemented within the FGPA 600, while those elements outside this block are external to it and in the exemplary embodiments are implemented in ARM software. Alternative embodiments apparent to one skilled in the art may include those where a high-speed DSP is used in place of the FPGA 600 to produce similar functions or in other cases, multiple FPGA units may work together to mimic those described in this disclosure. As the digital data is received by the FPGA 600, it is further down converted by the internal mixer 602 using a base frequency of 31.25 MHz, see local oscillator 601. This data may be filtered by a low-pass-filter (LFP) 603 to remove images prior to down-sampling (in this example by a ratio of 4 to 1) at the down-sampler 604 to produce a 31.25 MHz digital signal output 604b. Once down sampled, the data 604b is streamed into a digital buffer 605 where sufficient storage is present for collecting up to 4096 samples. At intervals when the digital buffer 605 is fully refreshed (immediately after use of prior stored data), these samples are supplied as input to a fast Fourier transform (FFT) 606, producing a frequency domain representation of the data of size equal to that for the input buffer 605. The resultant frequency domain samples are further processed through math block 607, where first the square of the magnitude, m²[k], for each frequency domain point is calculated by the sum of squares for the real, i[k], and complex portion, q[k], of each sample by summing their squares. Finally, the magnitude values, m[k], are converted into decibels (using the equation, s[k]=10*log₁₀(m²[k]). The FPGA 600 then supplies these decibel values to the touchscreen display for producing a color-coded trace 102 (after appropriate scaling) and if desired other information to be viewed on screen by the user such as illustrated in FIGS. 2, 3 or 4. Block 609 in FIG. 5 indicates that the plot is updated, e.g. with refresh rate in this example of 60 Hz. Block 609 also indicates that the various portions of the trace are associated with assigned colors when updating the plot. A novel feature of this invention is the presence of block 614 that supplies data on which frequency bands have been allocated for various commercial purposes, such as the presence of DTV stations operating in the area. This data may be utilized by block 609 for the purpose of labelling, boxing or shading various frequency bands on the RTSA trace 102. For some embodiments, the block 614 may be an EEPROM that is programed with factory settings prior to shipping, while in other embodiments, it may be made available for a user to reprogram for updating with the latest available information. While the method disclosed here relies on an FFT applied to a data buffer, it should be apparent to those skilled in the art that alternative methods are anticipated for generating the decibel data, s[k]. For example, in some embodiments, the FFT of an autocorrelation sequence may provide suitable information for generating an RTSA trace. For yet other embodiments, it may be desirable that the user be allowed to custom configure the EEPROM database 614 (manually enter customized data) regarding data on sources that they learn while in the process of working with the equipment.

Another stream of down sampled data 604c from the down sampler 604 can be used to produce audio so that a user can listen to the channel while the frequency and bandwidth are being adjusted and/or the RTSA trace is being displayed. This alternate stream of down sampled data 604c is decoded to produce digital audio data, e.g., PCM data, see block 610. Then, in FIG. 5, the digital audio data is converted to an analog signal, block 611, and filtered and amplified, block 612. The amplified analog signal is provided to a headphone jack 110 so the user can use headphones to listen to audio at the same time that the user is viewing the RTSA traces, and possibly adjusting channel frequency and/or bandwidth.

Still referring to FIG. 5, it may also be desirable to enable the receiver to determine audio level or receive audio level data from an audio meter. In this way, the audio level can then be displayed contemporaneously with RTSA trace 102. In FIG. 5, decoded audio data, block 610, can be used to update audio level and simulate real time audio level data, which can be displayed along with the RTSA trace. Alternatively, the receiver or receiver module can have a data port able to receive data from a stand-alone audio meter.

In yet other embodiments, a bidirectional communication link may be constructed between each wireless microphone receiver and its paired wireless microphone transmitter. This capability for the receiver to send data back to the transmitter is sometimes referred to the art as “backlink”. In these cases, embodiments are envisioned whereby a receiver could notify its paired transmitter (via backlink) to stop transmitting for a specified time period. This would provide a temporal window of opportunity for the receiver to measure RF levels without the influence of its communication over an RF band.

For example, in embodiments where a backlink is built into the hardware, the receiver for an RTP may instruct its paired transmitter to cease RF broadcasting for a predetermined period of time during which the receiver will have the opportunity to measure the RTSA trace for the combination of all devices present, except for its specified paired transmitter. This RTSA trace information is stored and presented on the RTSA touchscreen display 101 as shown in FIG. 4, along with a live RTSA trace during which the transmitter of the RTP is transmitting. This has the advantage of letting the user know more clearly what influences the collection of all the other devices are having specifically over the prospective band for the RTP. In some embodiments utilizing the invention from the '383 application, the software may be configured to display the RF spectrum using a multi-color line. Some users may prefer to set the color for segments of the line 102 from a list of preset colors for easier identification (e.g., blue across DTV frequency bands, yellow for portions of the output from other RTPs) to indicate the influence (and presence) of these sources.

Further modifications are envisioned by the '383 application where for example, based on stored RF levels taken with and without an RTP active, a measure of the signal to noise ratio (SNR) for this RTP may be inferred from the distance in the dB domain between these measurements. In some embodiments, the trace for RF level both with and without the RTP active may be displayed, whereas in others, users may prefer to view only the SNR, as derived from these measurements 102 stored in the receiver. In yet other embodiments, it may be preferable to program the system to allow the user to drag the SNR indicator line 104 left or right along the frequency axis, while displaying a numerical value for its length in dB at the positioned frequency.

Once the user powers up the units, the user can pick preferred frequency bands as explained previously. Also, it may be desirable to automatically scan for optimal band(s). For example, upon invoking an auto-scan function, the receiver may measure RF signal levels present within a sliding 200 kHz wide frequency window as a starting at the lower end of a preset range such as 169 MHz to 1525 MHz. For some embodiments, it may be useful to scan peak-hold measurements taken to catch the influence of intermittent sources. At the same time, frequency regions known to correspond to DTV transmission (as provided by the database 614) may be excluded from consideration. If a series of suitably (clean) bands are found, the receiver may sequentially assign an RTP to each of suitable band. While in the process of this, a receiver may communicate with the transmitters to turn off transmission during measurement and then enable the transmitter to turn on as they are assigned. This way the system can measure and choose the band with the best SNR characteristics for each RTP.

FIG. 6 illustrates a second exemplary embodiment of the invention in which the allocated frequency bands are determined at least in part using an algorithm to detect the presence of active DTV signals in the RTSA trace. It is advantageous for the receiver to automatically identify DTV stations on the RTSA that are active currently. The circuit 500A in FIG. 6 analyzes the electronic signature of potentially active DTV carrier frequencies to identify active DTV carriers in the RTSA trace. For example, DTV frequency bands in the United States (and other region 1 countries) are 6 MHz wide, and use the same common frequencies, namely: low VHF channels 2, 3, 4, 5, 6 (54-88 MHz), high VHF channels 7, 8, 9, 10, 11, 12, 13 (174-216 MHz) and UHF channels 14 through 36(470 -608 MHz). In the present examples, the low VHF channels use frequencies outside of the 169 MHz to 1525 MHz transmission range of the receiver. DTV carriers in the European Union are 8 MHz wide and also use common carrier frequencies.

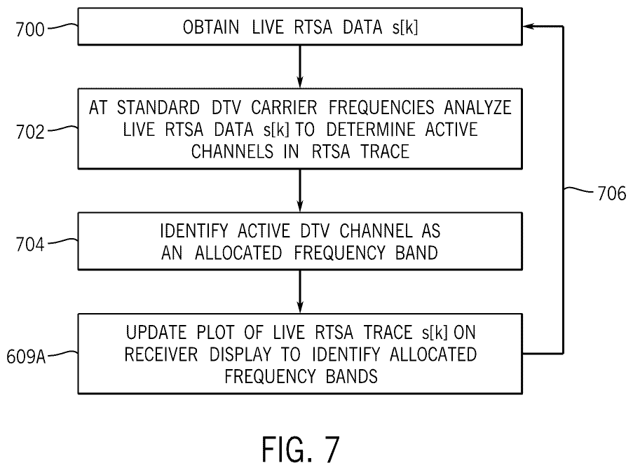

Referring still to FIG. 6, similar reference numbers are used as in FIG. 5 for the same components. The modifications in the circuit 500A in FIG. 6 compared to the circuit 500 in FIG. 5 pertain to the functions implemented by the processing of the RTSA trace s[k] in real time to identify active DTV signatures in the RTSA trace. In FIG. 6, the real-time RTSA trace, namely the s[k] values, are transmitted from the FPGA 600 to another processor (e.g., an ARM processor) that incorporates an algorithm to detect active DTV channels from s[k] values, as indicated by block 714. The s[k] values are transmitted to the microprocessor for updating the plot on the receiver display as indicated in block 609 and are also used by the microprocessor to detect active DTV channels from s[k] values. FIG. 7 describes the process of updating the plot of the RTSA data s[k] on the receiver display to designated allocated frequency bands corresponding to active DTV channels. The first step in FIG. 7 is for the microprocessor to obtain the live RTSA scan s[k], see block 700. As an example, the scanning can occur every 10 seconds.

The next step for the microprocessor is to implement an algorithm to analyze the live RTSA data s[k], at each standard DTV carrier, to determine active DTV channels in the live RTSA trace, see block 702 in FIG. 7. Then, each active DTV channel is identified as an allocated frequency band, see block 704. Preferably, once a DTV channel is found active and identified as an allocated frequency band, it remains an allocated frequency band until the receiver or receiver module is rebooted. Block 609A in FIG. 7 indicates that the next step is to update the plot of live RTSA data on the receiver display to designate allocated frequency bands.

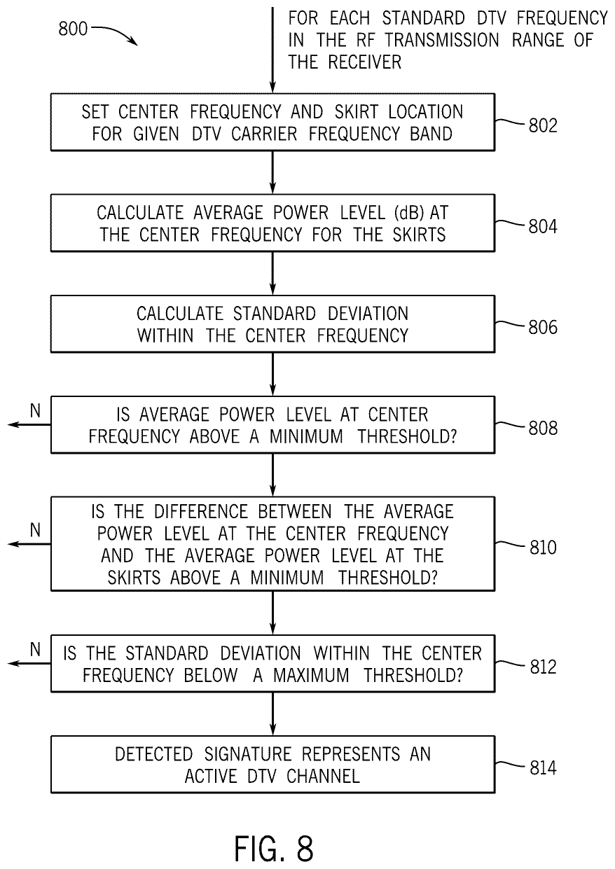

FIG. 8 describes an exemplary algorithm 800 for analyzing the real time RTSA data s[k] and detecting active DTV channels. The algorithm 800 is preferably implemented in ARM software on the receiver or receiver module. The algorithm 800 corresponds to the step of block 702 in FIG. 7, accordingly, is implemented at each standard DTV carrier frequency in the RTSA trace s[k]. Frequency tables in software can be used to look up the relevant DTV carrier frequency information. It is preferred that the algorithm can be skipped for a specific DTV carrier frequency that has already been detected as active and designated to be an allocated frequency band after a reboot.

Referring to the steps in FIG. 8, the first step 802 is to set the center frequency and skirt edge locations for the respective DTV carrier frequency within the wide frequency range (e.g. 169 MHz to 1525 MHz) of the receiver or receiver module, see block 802. The center frequency is the respective standard frequency for DTV channels in the given jurisdiction, e. g the DTV Channel 7 (US) has a center carrier frequency of 177 MHz with a full channel band of 174-180 MHz. The skirt width for the algorithm is discretionary but should be selected to represent the start and the end of the spectrum for the defined DTV channel, e.g. 300 kHz from the respective ends of the band. As an example, for DTV Channel 7 (US), suitable skirt locations are 174.3 MHz and 179.7 MHz. For the given channel, the algorithm 800 determines the average power level at the center frequency and at each end of the skirt, see block 804, and also determines a standard deviation within the center frequency, see block 806. Then, the algorithm 800 designates the given DTV channel as active (block 814) if the average power level at the center frequency is above a minimum center power threshold (block 808), the difference between the average power level at the center frequency and the average power level at the skirt ends is above a minimum threshold (block 810), and the standard deviation within the center of a defined TV channel is below a maximum threshold (block 812). As an example, to be considered present or active, the minimum average power level of the center of a defined TV channel can be set at −106 dB, block 808. In other words, the average power level at the center frequency should define a signal rather than noise. For block 810, the average power level of the center frequency of the defined TV channel is compared to the average power level of the skirts, and the difference must exceed a minimum threshold. In the present example, this difference should be greater than +5 dB for the channel to be considered present and active. In addition, for block 812, the standard deviation within the center of a defined TV channel should not exceed a maximum value. In the present example, the maximum standard deviation within the center of a defined TV channel, for the channel to be considered present and active is 7 dB. Only if all conditions, blocks 808, 810 and 812) above are met, will the DTV channel be identified as present and active (block 814). Once a DTV channel is identified as present and active (block 814), it will remain that way so long as the receiver or receiver module remains on, and the Show TV Channels setting remains enabled. The algorithm 800 will run repeatedly, analyzing and checking for the active presence of all defined DTV channels in the frequency range that the receiver is configured to scan. On the RTSA display, if a DTV Channel is detected as present and active, the TV channel can be shown in gray on the display, similar to other disallowed frequencies in certain bands, but distinguished by colors, box and/or labels as previously discussed.

The algorithm described in FIGS. 7 and 8 is an example of an algorithm that effectively detects active DTV signatures in a live RTSA trace s[k], but other algorithms may be suitable as well. Another exemplary algorithm is described below. For a given frequency range over which the receiver is configured to operate (e.g. 169 MHz to 1525 MHz), scan the frequencies of known DTV carriers. For instance, DTV Channel 14 is 470-476 MHz. The next step is to calculate the maximum signal level for frequencies of all antennas contributing to the signal (for instance, maximum of antennas A and B while in diversity mode). The next step is to calculate the average signal level across the DTV Channel (6 MHz if in the United States) for a given channel for the maximum of antenna A and B. This is preferably accomplished by integrating s[k] across the band, to obtain a single value in dBm, which for purposes of this explanation is designated “TV Level.” The next step is to scan the maximum of antenna signals A and B again, looking for how many sections of the signal have contiguous 25 kHz holes that are less than a hole threshold. The number of these holes is a hole count. An exemplary hole threshold is the TV Level −10 dB or −95, whichever is greater. With these values, a DTV signal is determined to be present and active if TV level >−90 dBm and the hole count is <8.

Besides the automatic detection of active DTV channels in RTSA trace, other features of the invention described with the in connection with the embodiments and variations of the invention described in FIGS. 1-5, can also be implemented in connection with the embodiment of the invention described in FIGS. 6 through 8.

### CONCLUSION

The construction and arrangement of the elements of the systems and methods as shown in the exemplary (and alternative) embodiments are illustrative only. Although only a few embodiments of the present disclosure have been described in detail, those skilled in the art will readily appreciate that many modifications are possible (e.g., variations in sizes, dimensions, structures, shapes and proportions of RTSA touchscreen display or the simultaneous presentation of parameters, or other modifications involving the arrangement, use of materials, colors, orientations, etc. for information provided) without materially departing from the novel teachings and advantages of the subject matter disclosed. For example, rather than drawing boxes embodiments that prove useful may include those where other graphical notifications are drawn such as bands, braces or even dynamic features such as pop-up warnings, flashing graphics or other symbols placed along relevant sections of the RTSA trace.

Also, as noted earlier, the invention can be implemented on a stand-alone receiver with a screen capable of displaying an RTSA trace and can be also applied to multiple receivers integrated into a receiver module or into other equipment such as a mixer-recorder. Several stand-alone receivers implementing the invention can be mounted in racks or can be distributed on the stage or set. In one particular advantageous embodiment, the several multi-receiver modules are dispersed at different locations on a stage or set, and each of the receivers implements the ability to generate and display RTSA traces, labels and graphics as described herein. Desirably, the several multi-receiver modules are connected to one another, e.g., via an Ethernet connection, and the various RTSA traces can be viewed on the screens for the other receivers, or a hub or a computer connected to the system. In addition, the circuits in FIGS. 5 and 6 can be duplicated as needed to provide an RTSA trace for additional antennas on a given receiver or receiver module. Alternatively, multiple antennae signals available for a given receiver channel can be combined prior to inputting the circuits of FIGS. 5 and 6 if it is desired to determine an RTSA trace for the composite antenna output.

1. A wireless receiver or receiver module in a sound recording system, comprising:
at least one antenna that receives RF signals over a wide frequency range and outputs an antenna signal;
means for configuring the receiver and a paired microphone transmitter over to a selected channel frequency band, wherein the RF signals being received by the antenna over the wide frequency range include audio data transmitted from the paired microphone transmitter via an RF signal in the selected channel frequency band;
a real-time spectrum analyzer (RTSA) in the receiver or receiver module that generates an RTSA trace from the antenna signal,
a display on receiver or receiver module, wherein the RTSA trace is displayed in real time for the user view on the display;
means to determine allocated frequency bands, wherein said means to determine allocated frequency bands comprises an algorithm to detect the presence of active DTV channels in the RTSA trace; and
means to identify one or more allocated frequency bands on the display when the RTSA trace is displayed in real time.

2. (canceled)

3. The wireless receiver or receiver module according to claim 1 wherein once the algorithm detects a given DTV channel to be active, the given DTV channel remains an allocated frequency band that is identified on the display until the receiver or receiver module is rebooted.

4. The wireless receiver or receiver module according to claim 1 wherein the algorithm detects active DTV channels in the RTSA trace by implementing the following steps: designating a center frequency and skirt for each expected DTV channel within the wide frequency range; determining average power level at the center frequency and at the each end of the skirt, and determining a standard deviation of the center frequency; and designating the given DTV channel as active if the average power level at the center frequency is above a minimum center power threshold, the difference between the average power level at the center frequency and the average power level at the skirt ends is above a minimum.

5. (canceled)

6. The wireless receiver or receiver module according to claim 1 wherein the means to identify one or more allocated frequency bands on the display when the RTSA trace is displayed in real time comprises boxes, braces or lines identifying the boundary of the respective allocated frequency band, shading of the region on the display identifying the boundary of the respective allocated frequency band, and/or dynamic indicia alerting users to the respective allocated frequency band.

7. The wireless receiver or receiver module according to claim 1 wherein said means to identify one or more allocated frequency bands on the display when the RTSA trace is displayed in real time includes means to name the portion of the RTSA trace corresponding to the one or more respective allocated frequency bands and label the portion of the RTSA trace corresponding to the one or more respective allocated frequency bands with the name or names when displayed.

8. The wireless receiver or receiver module according to claim 6 wherein said means to identify one or more allocated frequency bands on the display when the RTSA trace is displayed in real time are color coded depending on the type of RF transmission that a specific portion of the spectrum has been allocated.

9. (canceled)

10. The wireless receiver or receiver module according to claim 1 wherein the portion of the RTSA trace corresponding to the selected channel frequency band is displayed to be distinct from the remainder of the RTSA trace.

11. (canceled)

12. The wireless receiver or receiver module according to claim 7 comprising means to name the portion of the RTSA trace corresponding to the selected channel frequency band and label the portion of the RTSA trace corresponding to the selected channel frequency band with the name when displayed.

13. The wireless receiver or receiver module according to claim 1 further comprising at least one additional antenna operating in diversity with said antenna to output the RF signal.

14. The wireless receiver or receiver module according to claim 10 comprising:
means to name the portion of the RTSA trace corresponding to the selected channel frequency band and label the portion of the RTSA trace corresponding to the selected channel frequency band with the name when displayed;
means to name the portion or portions of the RTSA trace corresponding to the channel frequency bands for the additional receiver and transmitter pairs and label the portion or portions of the RTSA trace corresponding to the additional receiver and transmitter pairs with the name when displayed; and
wherein said means to identify one or more selected allocated frequency bands on the display when the RTSA trace is displayed in real time includes means to name the portion of the RTSA trace corresponding to the one or more selected allocated frequency bands and label the portion of the RTSA trace corresponding to the one or more selected allocated frequency bands with the name or names when displayed.

15. The wireless receiver or receiver module as recited in claim 1 wherein a peak and hold feature is implemented by scanning the RTSA scan and tabulating when RF power levels at a given frequency exceed a threshold and subsequently identifying frequency regions that have been, even intermittently, subject to RF power levels above the threshold.

16. The wireless receiver or receiver module as recited in claim 1 wherein said means for configuring the receiver and a paired microphone transmitter over to a selected channel frequency band is blocked from setting the channel frequency band within one or more allocated frequency bands.

17. The wireless receiver or receiver module according to claim 1 wherein the receiver or receiver module further comprises a touch screen and the RTSA trace is displayed on the touch screen.

18. The wireless receiver or receiver module according to claim 1 wherein the RTSA comprises an analog circuit that receives the antenna signal and filters, amplifies and down coverts the analog signal, an analog-to-digital converter that receives the analog signal from the analog circuit and outputs a digital input signal, and a processor that receives the digital input signal and outputs values representing decibels for a given frequency; and further wherein the processor communicates with said means to determine allocated frequency bands and further outputs instructions to identify said one or more identified allocated frequency bands on the display when the RTSA trace is displayed in real time.

19. The wireless receiver or receiver module according to claim 1 wherein said means for configuring the receiver and a paired microphone transmitter over to a selected channel frequency band comprises an auto assign function in which the respective RTP channels are assigned to frequency bands outside of the one or more allocated frequency bands and having levels of interference and noise below a set threshold.
